(19) United States
(12) Patent Application Publication
(10) Pub. No.: US 2025/0296870 A1
(43) Pub. Date: Sep. 25, 2025

(54) GLASS COMPOSITION, GLASS ARTICLE PREPARED THEREFROM, DISPLAY DEVICE AND ELECTRONIC DEVICE

(71) Applicants: Samsung Display Co., Ltd., Yongin-si (KR); KONGJU NATIONAL UNIVERSITY INDUSTRY-UNIVERSITY COOPERATION FOUNDATION, Gongju-si (KR)

(72) Inventors: Seungho Kim, Yongin-si (KR); Woon Jin Chung, Seongnam-si (KR); Namsoo Kang, Yongin-si (KR); Byeongbeom Kim, Yongin-si (KR); Seung Kim, Yongin-si (KR); Jinsu Nam, Yongin-si (KR); Kyeongdae Park, Cheonan-si (KR); Seongyoung Park, Cheonan-si (KR); Cheolmin Park, Yongin-si (KR); Gyuin Shim, Yongin-si (KR); Jaegil Lee, Yongin-si (KR); Jinwook Jang, Seongnam-si (KR); Jinwon Jang, Yongin-si (KR)

(73) Assignees: Samsung Display Co., Ltd., Yongin-si (KR); KONGJU NATIONAL UNIVERSITY INDUSTRY-UNIVERSITY COOPERATION FOUNDATION, Gongju-si (KR)

(21) Appl. No.: 19/086,615

(22) Filed: Mar. 21, 2025

(30) Foreign Application Priority Data
Mar. 22, 2024 (KR) 10-2024-0039982

(51) Int. Cl. C03C 3/085; H10K 59/80; H10K 102/00

(52) U.S. Cl. CPC C03C 3/085; H10K 59/873; H10K 2102/351

(57) ABSTRACT

A glass article includes a glass composition including SiO₂ in a range of about 60 mol % to about 70 mol %, Al₂O₃ in a range of about 5 mol % to about 15 mol %, Na₂O in a range of about 5 mol % to about 15 mol %, Li₂O in a range of about 5 mol % to about 15 mol %, and MgO greater than 0 mol % and less than or equal to about 5 mol % with respect to a total weight of the glass composition, the glass composition satisfies Relation 1 (0.3≤Al₂O₃/(a sum of Na₂O and Li₂O)≤1.0, wherein Al₂O₃, Na₂O and Li₂O represent contents of respective components in mol %), and a thickness of the glass article is in a range of about 20 μm to about 100 μm.

### CROSS-REFERENCE TO RELATED APPLICATION(S)

This application claims priority to and benefits of Korean Patent Application No. 10-2024-0039982 under 35 U.S.C. § 119, filed on Mar. 22, 2024, in the Korean Intellectual Property Office (KIPO), the entire contents of which are incorporated herein by reference.

### BACKGROUND

### 1. Technical Field

One or more embodiments relate to a glass composition, a glass article prepared therefrom, a display device and an electronic device.

### 2. Description of the Related Art

Glass articles are widely used in electronic devices including display panels or as construction materials. For example, glass articles are applied to substrates of flat display panels, such as liquid crystal display (LCD) panels, organic light-emitting display (OLED) panels, or electrophoretic display panels or cover windows protecting the same.

As portable electronic devices, for example, smartphones or tablet personal computers (PCs), increase, glass articles applied thereto are frequently exposed to external impact. For portability, there is a need for glass articles that are thin yet may withstand external impact.

Recently, there has been research on foldable electronic devices including display panels for user convenience. It is advisable for glass articles applied to foldable electronic devices to have small thicknesses and strength sufficient enough to withstand external impact to relieve bending stresses when the glass articles are folded. In addition, when the foldable electronic devices are repeatedly folded, it is desirable to reduce creases that may be generated during repeated folding operations.

### SUMMARY

One or more embodiments provide a glass composition in which impact resistance is improved while the generation of creases is reduced in a glass folding area, a glass article prepared therefrom, a display device and an electronic device. However, this is merely an example, and the scope of the disclosure is not limited thereto.

Additional aspects will be set forth in part in the description which follows and, in part, will be apparent from the description, or may be learned by practice of the embodiments of the disclosure.

According to an embodiment, a glass article may include a glass composition including SiO₂ in a range of about 60 mol % to about 70 mol %, Al₂O₃ in a range of about 5 mol % to about 15 mol %, Na₂O in a range of about 5 mol % to about 15 mol %, Li₂O in a range of about 5 mol % to about 15 mol %, and MgO greater than 0 mol % and less than or equal to about 5 mol % with respect to a total weight of the glass composition. The glass composition may satisfy Relation 1, and a thickness of the glass article is in a range of about 20 μm to about 100 μm.

0.3≤Al₂O₃/(the sum of Na₂O and Li₂O) (an R ratio)≤1.0 [Relation 1]

in Relation 1, Al₂O₃, Na₂O and Li₂O may represent contents of respective components in mol %.

An elastic modulus of the glass article may be in a range of about 75 GPa to about 85 GPa.

A brittleness of the glass article may be in a range of about 4.9 μm^{-0.5} to about 5.6 μm^{-0.5}.

A coefficient of thermal expansion of the glass article may be in a range of about 85*10⁻⁷ K⁻¹ to about 120*10⁻⁷ K⁻¹.

A glass transition temperature of the glass article may be in a range of about 425° C. to about 525° C.

A density of the glass article may be in a range of about 2.38 g/cm³ to about 2.48 g/cm³.

A Poisson's ratio of the glass article may be in a range of about 0.20 to about 0.28.

A Vickers hardness of the glass article may be in a range of about 5.50 GPa to about 6.50 GPa.

A fracture toughness of the glass article may be in a range of about 0.75 MPa*m^{0.5} to about 0.85 MPa*m^{0.5}.

The glass article may be foldable.

The glass composition may further satisfy Relation 2.

0.3≤Al₂O₃/(a sum of Na₂O, Li₂O, and MgO)≤1.0 [Relation 2]
in Relation 2, Al₂O₃, Na₂O and MgO may represent contents of respective components in mol %.

According to an embodiment, a glass composition may include SiO₂ in a range of about 60 mol % to about 70 mol %, Al₂O₃ in a range of about 5 mol % to about 15 mol %, Na₂O in a range of about 5 mol % to about 15 mol %, Li₂O in a range of about 5 mol % to about 15 mol %, and MgO greater than 0 mol % and less than or equal to about 5 mol % with respect to a total weight of the glass composition. The glass composition may satisfy Relation 1.

0.3≤Al₂O₃/(a sum of Na₂O and Li₂O)≤1.0 [Relation 1]

In Relation 1, Al₂O₃, Na₂O and Li₂O may represent contents of respective components in mol %.

According to an embodiment, a display device may include a display panel including a plurality of pixels and a cover window disposed on the display panel. The cover window may include, as a glass composition, SiO₂ in a range of about 60 mol % to about 70 mol %, Al₂O₃ in a range of about 5 mol % to about 15 mol %, Na₂O in a range of about 5 mol % to about 15 mol %, Li₂O in a range of about 5 mol % to about 15 mol %, and MgO greater than 0 mol % and less than or equal to about 5 mol % with respect to a total weight of the cover window. The glass composition may satisfy Relation 1, and a thickness of the cover window may be in a range of about 20 μm to about 100 μm.

0.3≤Al₂O₃/(a sum of Na₂O and Li₂O)≤1.0 [Relation 1]

In Relation 1, Al₂O₃, Na₂O and Li₂O may represent contents of respective components in mol %.

An elastic coefficient of the cover window may be in a range of about 75 GPa to about 85 GPa.

A brittleness of the cover window may be in a range of about 4.9 μm^{-0.5} to about 5.6 μm^{-0.5}.

A coefficient of thermal expansion of the cover window may be in a range of about 85*10⁻⁷ K⁻¹ to about 120*10⁻⁷ K⁻¹.

A glass transition temperature of the cover window may be in a range of about 425° C. to about 525° C.

A density of the cover window may be in a range of about 2.38 g/cm³ to about 2.48 g/cm³.

A Poisson's ratio of the cover window may be in a range of about 0.20 to about 0.28.

A Vickers hardness of the cover window may be in a range of about 5.50 GPa to about 6.50 GPa.

A fracture toughness of the cover window may be in a range of about 0.75 MPa*m^{0.5} to about 0.85 MPa*m^{0.5}.

According to an embodiment, an electronic device may include a display panel including a plurality of pixels and a cover window disposed on the display panel. The cover window may include, as a glass composition, SiO₂ in a range of about 60 mol % to about 70 mol %, Al₂O₃ in a range of about 5 mol % to about 15 mol %, Na₂O in a range of about 5 mol % to about 15 mol %, Li₂O in a range of about 5 mol % to about 15 mol %, and MgO greater than 0 mol % and less than or equal to about 5 mol % with respect to a total weight of the cover window. The glass composition may satisfy Relation 1, and a thickness of the cover window may be in a range of about 20 μm to about 100 μm.

0.3≤Al₂O₃/(a sum of Na₂O and Li₂O)≤1.0 [Relation 1]

The electronic device may include a mobile phone, a smartphone, a tablet PC, a mobile communication terminal, a personal digital assistant, an e-book terminal, a portable multimedia player (PMP), a navigation device, an ultra-mobile PC (UMPC), a TV, a laptop, a monitor, a billboard, or an Internet of Things (IoT) device.

### BRIEF DESCRIPTION OF THE DRAWINGS

The above and other aspects, features, and advantages of embodiments of the disclosure will be more apparent from the following description taken in conjunction with the accompanying drawings, in which:

FIGS. 1A, 1B, 1C, and 1D are each a perspective view of a glass article according to an embodiment;

FIGS. 2 and 3 are schematic perspective views of an electronic device to which a glass article is applied, according to an embodiment;

FIG. 4 is a schematic cross-sectional view of a portion of an electronic device according to an embodiment;

FIG. 5 is a schematic cross-sectional view of a glass article according to an embodiment; and

FIG. 6 is a graph showing a stress profile of a glass article, according to an embodiment.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description.

As the disclosure allows for various changes and numerous embodiments, particular embodiments will be shown in the drawings and described in detail in the written description. The attached drawings for illustrating embodiments of the disclosure are referred to in order to gain a sufficient understanding of the disclosure, the merits thereof, and the objectives accomplished by the implementation of the disclosure. The disclosure may, however, be embodied in many different forms and should not be construed as being limited to the embodiments set forth herein.

It will be understood that although the terms “first,” “second,” etc. may be used herein to describe various elements, these elements should not be limited by these terms, and these elements are only used to distinguish one element from another.

As used herein, the singular forms “a,” “an,” and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components.

Sizes of elements in the drawings may be exaggerated for convenience of explanation. In other words, since sizes and thicknesses of elements in the drawings are arbitrarily illustrated for convenience of explanation, the following embodiments are not limited thereto.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

In the following examples, the x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments of the disclosure will be described in detail with reference to the accompanying drawings. Like elements in the drawings denote like elements, and repeated descriptions thereof are omitted.

Glass is used for cover windows for protecting displays in electronic devices, for example, tablet personal computers (PCs), laptops, smartphones, electronic books, televisions (TVs), PC monitors as well as refrigerators and washing machines with displays, substrates for display panels, substrates for touch panels, or optical members such as light guide plates. Glass may also be used for cover glass in, for example, dashboards of vehicles, cover glass for solar cells, interior materials for construction, or windows for buildings or houses.

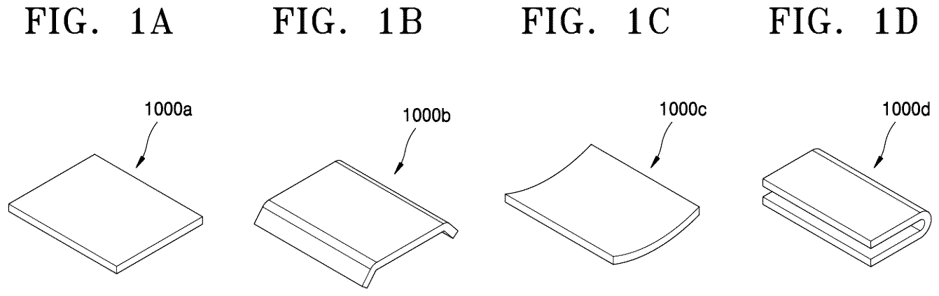

Such glass needs to have great strength. For example, it is advisable for glass for windows to be thin to satisfy requirements, such as high transmittance and light weight, and also have a strength not to be readily broken by external impact. Glass with increased strength may be manufactured in various manners such as chemical or thermal strengthening. FIGS. 1A-1D show embodiments of glass articles having various shapes.

As shown in FIG. 1A, in an embodiment, a glass article 1000a may be a flat-plate sheet or a flat plate. In another embodiment, as shown in FIGS. 1B, 1C, and 1D, glass articles 1000b, 1000c, and 1000d may have three-dimensional shapes including bent portions. For example, as shown in FIG. 1B, the glass article 1000b may have a flat portion with curved edges. For example, as shown in FIG. 1C, the glass article 1000c may be generally curved. For example, as shown in FIG. 1D, the glass article 1000d may be folded. In another embodiment, the glass article 1000a may be a foldable glass article that is shaped as a flat-plate sheet or a flat plate and is foldable or bendable with flexibility. In another embodiment, the glass article 1000a may be stretchable or rollable.

The planar shapes of the glass articles 1000a to 1000d may be rectangular, but the disclosure is not limited thereto. The shapes may vary, for example, the shapes of the glass articles 1000a to 1000d may be a rectangle with rounded edges, a square, a circle, or an oval in a plan view. In embodiments below, the glass articles 1000a to 1000d are described as rectangular flat plates, but the disclosure is not limited thereto.

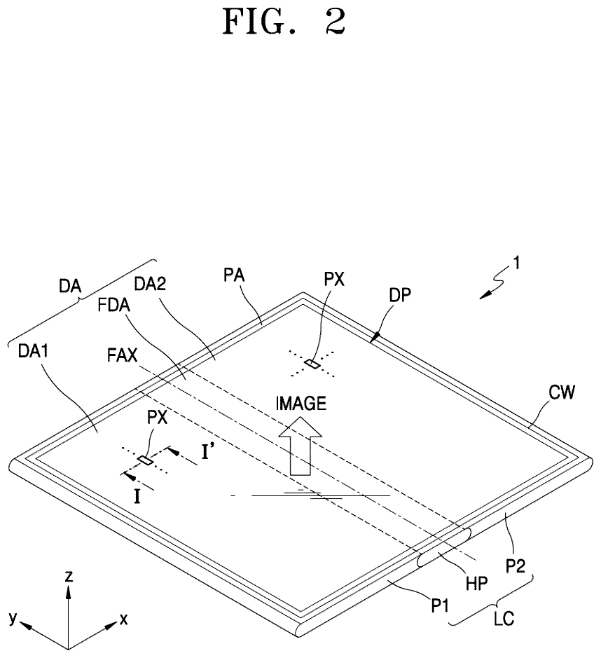

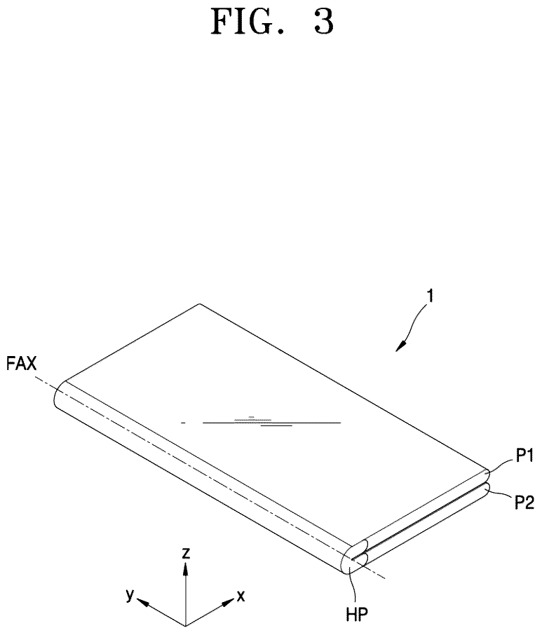

FIGS. 2 and 3 are schematic perspective views of an electronic device 1 to which a glass article is applied, according to an embodiment. In detail, FIG. 2 shows the electronic device 1 in an unfolded state, while FIG. 3 shows the electronic device 1 in a folded state.

Referring to FIGS. 2 and 3, the electronic device 1 may include a lower cover LC, a display panel DP, and a cover window CW. The electronic device may include a display device. The display device may include the display panel DP and the cover window CW. The electronic device 1 according to an embodiment may be a foldable electronic device. The cover window CW may be the glass article described with reference to FIGS. 1A to 1D, and the glass article may be folded with flexibility.

The lower cover LC may include a first portion P1 and a second portion P2 that support the display panel DP. The lower cover LC may be foldable with respect to a folding axis FAX defined between the first portion P1 and the second portion P2. In an embodiment, the lower cover LC may further include a hinge portion HP, and the hinge portion HP may be disposed between the first portion P1 and the second portion P2.

The display panel DP may provide images IMAGE and include a display area DA and a peripheral area PA adjacent to the display area DA.

In the display area DA, multiple pixels PX may be arranged and images IMAGE may be provided through an array of the pixels PX. Each pixel PX may be defined as an emission area where light is emitted from a light-emitting element electrically connected to a pixel circuit. In an embodiment, each pixel PX may emit red light, green light, or blue light. In another embodiment, each pixel PX may emit red light, green light, blue light, or white light.

The peripheral area PA may be a non-display area where no images are provided, and in the peripheral area PA, various lines, driving circuits, and the like may be arranged to provide electrical signals or power to the display area DA.

The light-emitting element included in the display panel DP may include an organic light-emitting diode, an inorganic light-emitting diode, a micro-light-emitting diode, and/or a quantum dot emitting diode. Hereinafter, for convenience, an embodiment that the light-emitting element included in the display panel DP includes an organic light-emitting diode is described, but the descriptions below are not limited thereto. The display panel DP may include other types of light-emitting elements.

The display area DA may include a first display area DA1 and a second display area DA2 located on sides of the display area DA with respect to the folding axis FAX intersecting the display area DA. In an embodiment, the display area DA may include a folding area FDA between the first display area DA1 and the second display area DA2. For example, the first display area DA1, the second display area DA2, and the folding area FDA may individually provide independent images, or the first display area DA1, the second display area DA2, and the folding area FDA may provide one image as a whole.

The first display area DA1 and the second display area DA2 may overlap the first portion P1 and the second portion P2 of the lower cover LC in a thickness direction of the display panel DP, respectively. The folding area FDA may overlap the hinge portion HP of the lower cover LC in the thickness direction. The display panel DP may be foldable with respect to the folding axis FAX. The folding area FDA may be bent as the display panel DP is folded. In case that the display panel DP is folded, the first display area DA1 may face the second display area DA2.

FIGS. 2 and 3 show the folding axis FAX extending in a y direction, but the disclosure is not limited thereto. In another embodiment, the folding axis FAX may extend in an x direction intersecting the y direction. In another embodiment, in a xy plane, the folding axis FAX may extend in a direction intersecting the x direction and the y direction.

FIGS. 2 and 3 also show that is the electronic device 1 includes one folding axis FAX, but the disclosure is not limited thereto. In another embodiment, the display panel DP may include multiple folding axes FAX intersecting the display area DA and may be foldable multiple times with respect to the folding axes FAX.

The cover window CW may be disposed on the display panel DP and cover the display panel DP. The cover window CW may be foldable or bendable in response to external impact without cracks. In case that the display panel DP is folded with respect to the folding axis FAX, the cover window CW may also be folded.

In a plan view, the shape of the electronic device 1 may be substantially a rectangle. For example, as shown in FIG. 2, the electronic device 1 may generally have a rectangular shape in a plan view with sides extending in a first direction (e.g., the x direction) and sides extending in a second direction (e.g., the y direction). In an embodiment, corners, at which the sides of the electronic device 1 in the first direction meet the sides in the second direction, may have right-angled shapes or round shapes with a curvature. The planar shape of the electronic device 1 is not limited to a rectangle and may vary; for example, the shape of the electronic device 1 may be a circle, an oval, a polygon such as a triangle, or an atypical shape.

The electronic device 1 may be a product in various product groups, for example, a portable electric device such as a mobile phone, a smartphone, a tablet PC, a mobile communication terminal, a personal digital assistant, an e-book terminal, a portable multimedia player (PMP), a navigation device, or an ultra-mobile PC (UMPC), a TV, a laptop, a monitor, a billboard, an Internet of Things (IoT) device, and the like.

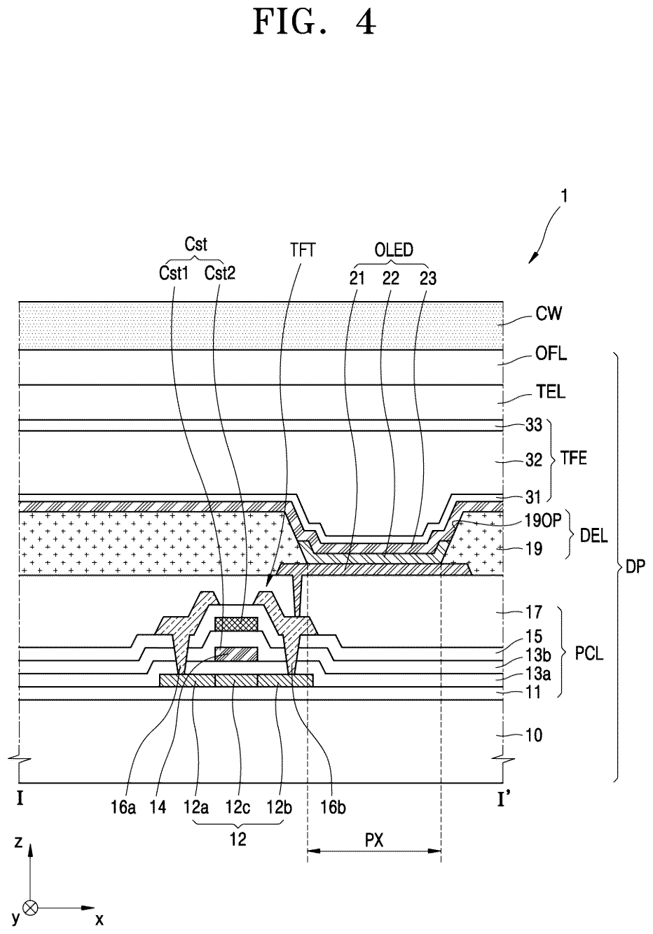

FIG. 4 is a schematic cross-sectional view of a portion of the electronic device 1 according to an embodiment. FIG. 4 is a schematic cross-sectional view of the display panel DP and the cover window CW of the display device, taken along a line I-I′ of FIG. 2.

Referring to FIG. 4, the display panel DP may include a stack structure including a substrate 10, a pixel circuit layer PCL, a display element layer DEL, a thin-film encapsulation layer TFE, a touch electrode layer TEL, and an optical functional layer OFL.

The substrate 10 may include glass or a polymer resin. For example, the substrate 10 may include a polymer resin including polyether sulfone, polyarylate, polyetherimide, polyethylene naphthalate, polyethylene terephthalate, polyphenylene sulfide, polyimide, polycarbonate, cellulose triacetate, cellulose acetate propionate, or the like.

The pixel circuit layer PCL may be disposed over the substrate 10. FIG. 4 shows that the pixel circuit layer PCL includes a thin-film transistor TFT, and a buffer layer 11, a first insulating layer 13a, a second insulating layer 13b, a third insulating layer 15, and a planarization layer 17 which are disposed under and/or over components of the thin-film transistor TFT.

The buffer layer 11 may decrease or prevent the penetration of foreign materials, moisture, or external air from the bottom of the substrate 10 and provide a flat surface on the substrate 10. The buffer layer 11 may include an inorganic insulating material, such as silicon nitride (SiNₓ), silicon oxynitride (SiON), and silicon oxide (SiO₂) and may be a layer or layers including the inorganic insulating material.

The thin-film transistor TFT on the buffer layer 11 may include a semiconductor layer 12, and the semiconductor layer 12 may include polysilicon. In another embodiment, the semiconductor layer 12 may include amorphous silicon, an oxide semiconductor, an organic semiconductor, or the like. The semiconductor layer 12 may include a channel area 12c and a drain area 12a and a source area 12b respectively arranged on sides of the channel area 12c. A gate electrode 14 may overlap the channel area 12c in the thickness direction.

The gate electrode 14 may include a low-resistive metal material. The gate electrode 14 may include a conductive material such as molybdenum (Mo), aluminum (Al), copper (Cu), or titanium (Ti) and may be a layer or layers including the above material.

The first insulating layer 13a may be arranged between the semiconductor layer 12 and the gate electrode 14. The first insulating layer 13a may include an inorganic insulating material, such as SiO₂, SiNₓ, SiON, aluminum oxide (Al₂O₃), titanium oxide (TiO₂), tantalum oxide (Ta₂O₅), hafnium oxide (HfO₂), or zinc oxide (ZnO).

The second insulating layer 13b may cover the gate electrode 14. The second insulating layer 13b may include an inorganic insulating material, such as SiO₂, SiNₓ, SiON, Al₂O₃, TiO₂, Ta₂O₅, HfO₂, or ZnO.

An upper electrode Cst2 of a storage capacitor Cst may be disposed over the second insulating layer 13b. The upper electrode Cst2 may at least partially overlap the gate electrode 14 in the thickness direction. The gate electrode 14 and the upper electrode Cst2, which overlap each other with the second insulating layer 13b interposed between the gate electrode 14 and the upper electrode Cst2, may form a storage capacitor Cst. For example, the gate electrode 14 may function as a lower electrode Cst1 of the storage capacitor Cst.

As described, the storage capacitor Cst may overlap the thin-film transistor TFT in the thickness direction. In another embodiment, the storage capacitor Cst may not overlap the thin-film transistor TFT. For example, as a component separate from the gate electrode 14, the lower electrode Cst1 of the storage capacitor Cst may be formed apart from the gate electrode 14.

The upper electrode Cst2 may include Al, platinum (Pt), palladium (Pd), silver (Ag), magnesium (Mg), gold (Au), nickel (Ni), neodymium (Nd), iridium (Ir), chromium (Cr), calcium (Ca), Mo, Ti, tungsten (W), and/or Cu and may be a layer or layers including the above material.

The third insulating layer 15 may cover the upper electrode Cst2. The third insulating layer 15 may include SiO₂, SiNₓ, SiON, Al₂O₃, TiO₂, Ta₂O₅, HfO₂, ZnO, or the like. The third insulating layer 15 may be a layer or layers including the above inorganic insulating material.

A drain electrode 16a and a source electrode 16b may each be disposed over the third insulating layer 15. The drain electrode 16a and the source electrode 16b may be respectively connected to the drain area 12a and the source area 12b through contact holes formed in insulating layers under the drain electrode 16a and the source electrode 16b. The drain electrode 16a and the source electrode 16b may each include a material with good conductivity. The drain electrode 16a and the source electrode 16b may each include a conductive material such as Mo, Al, Cu, or Ti and may be a layer or layers including the above material. In an embodiment, the drain electrode 16a and the source electrode 16b may have a multilayered structure of Ti/Al/Ti.

The planarization layer 17 may include an organic insulating layer. The planarization layer 17 may include an organic insulating material such as a general-purpose polymer such as polymethylmethacrylate (PMMA) or polystyrene (PS), a polymer derivative having a phenol-based group, an acryl-based polymer, an imide-based polymer, an aryl-ether-based polymer, an amide-based polymer, a fluorine-based polymer, a p-xylene-based polymer, a vinyl alcohol-based polymer, and a blend thereof.

The display element layer DEL may be disposed over the pixel circuit layer PCL having the above-described structure. The display element layer DEL may include an organic light-emitting diode OLED as a light-emitting element, and the organic light-emitting diode OLED may have a stack structure including a first electrode 21, an emission layer 22, and a second electrode 23. The first electrode 21 of the organic light-emitting diode OLED may be electrically connected to the thin-film transistor TFT through a contact hole defined in the planarization layer 17.

The first electrode 21 may include a conductive oxide, such as indium tin oxide (ITO), indium zinc oxide (IZO), ZnO, indium oxide (In₂O₃), indium gallium oxide (IGO), or aluminum zinc oxide (AZO). In an embodiment, the first electrode 21 may include a reflection layer including Ag, Mg, Al, Pt, Pd, Au, Ni, Nd, Ir, Cr, or a compound thereof. In an embodiment, the first electrode 21 may further include a layer including ITO, IZO, ZnO, or In₂O₃ on/under the above reflection layer.

On the first electrode 21, a pixel-defining layer 19 including an opening 19OP exposing at least a portion of the first electrode 21 may be arranged. The pixel-defining layer 19 may include an organic insulating material and/or an inorganic insulating material. The opening 19OP may define an emission area of light emitted from the organic light-emitting diode OLED. For example, the size/width of the opening 19OP may correspond to the size/width of the emission area. Therefore, the size and/or the width of the pixel PX may depend on the size and/or the width of the opening 19OP of the pixel-defining layer 19.

The emission layer 22 may be arranged in the opening 19OP of the pixel-defining layer 19. The emission layer 22 may include a high-molecular-weight or low-molecular-weight organic material emitting light of a color. In another embodiment, the emission layer 22 may include an inorganic emission material or quantum dots.

Although not shown in FIG. 4, a first functional layer and a second functional layer may be arranged under and on the emission layer 22, respectively. The first functional layer may include, for example, a hole transport layer (HTL) or both an HTL and a hole injection layer (HIL). The second functional layer may include an electron transport layer (ETL) and/or an electron injection layer (EIL). However, the disclosure is not limited thereto. The first functional layer and the second functional layer may be selectively arranged on and under the emission layer 22, respectively. The first functional layer and/or the second functional layer may each be a common layer formed to entirely cover the substrate 10, similar to the second electrode 23 described below.

The second electrode 23 may be on the first electrode 21 and overlap the first electrode 21 in the thickness direction. The second electrode 23 may include a conductive material having a low work function. For example, the second electrode 23 may include a transparent (or translucent) layer including Ag, Mg, Al, Pt, Pd, Au, Ni, Nd, Ir, Cr, Li, Ca, or an alloy thereof. In an embodiment, the second electrode 23 may further include a layer including ITO, IZO, ZnO, or In₂O₃ on the transparent (or translucent) layer including the above material. The second electrode 23 may be integrally formed to entirely cover the substrate 10.

An encapsulation member may be disposed over the display element layer DEL. In an embodiment, the encapsulation member may be prepared as the thin-film encapsulation layer TFE. The thin-film encapsulation layer TFE may be arranged on and cover the display element layer DEL. The thin-film encapsulation layer TFE may include at least one inorganic encapsulation layer and at least one organic encapsulation layer. In an embodiment, the thin-film encapsulation layer TFE may include a first inorganic encapsulation layer 31, an organic encapsulation layer 32, and a second inorganic encapsulation layer 33 which are sequentially stacked. In another embodiment, the encapsulation member may be prepared as an encapsulation substrate.

The first inorganic encapsulation layer 31 and the second inorganic encapsulation layer 33 may each include at least one of Al₂O₃, TiO₂, Ta₂O₅, HfO₂, ZnO, SiO₂, SiNₓ, and SiON. The organic encapsulation layer 32 may include a polymer-based material. The polymer-based material may include an acrylic resin, an epoxy-based resin, polyimide, polyethylene, and the like. In an embodiment, the organic encapsulation layer 32 may include acrylate. The organic encapsulation layer 32 may be formed by curing a monomer or applying a polymer.

The touch electrode layer TEL including touch electrodes may be disposed over the thin-film encapsulation layer TFE, and the optical functional layer OFL may be disposed over the touch electrode layer TEL. The touch electrode layer TEL may obtain coordinate information according to an external input, e.g., a touch event. The optical functional layer OFL may reduce the reflectivity of light (external light) that is incident towards the electronic device 1 from the outside and/or may improve the color purity of light emitted from the electronic device 1.

In an embodiment, the optical functional layer OFL may include a retarder and/or a polarizer. The retarder may be of a film type or a liquid crystal coating type and may include a λ/2 retarder and/or a λ/4 retarder. The polarizer may also be of a film type or a liquid crystal coating type. The film type may include a stretched synthetic resin film, and the liquid crystal coating type may include liquid crystals arranged in a certain arrangement. The retarder and the polarizer may further include a protective film.

In an embodiment, the optical functional layer OFL may include a destructive interference structure. The destructive interference structure may include a first reflection layer and a second reflection layer disposed on different layers. First reflection light and second reflection light, which are respectively reflected from the first reflection layer and the second reflection layer, may destructively interfere with each other, and the reflectivity of external light may decrease accordingly.

An adhesive member may be arranged between the touch electrode layer TEL and the optical functional layer OFL. General adhesive members may be employed without limitation. For example, the adhesive member may be a pressure-sensitive adhesive (PSA).

The cover window CW may be disposed over the display panel DP. The cover window CW may be attached to the display panel DP by an adhesive member.

The cover window CW may have high transmittance to transmit light emitted from the display panel DP. In an embodiment, the transmittance of the cover window CW may be at least about 85%, and the haze of the cover window CW may be less than or equal to about 2%, but the disclosure is not limited thereto.

In an embodiment, the cover window CW may have a small thickness to reduce the weight of the electronic device 1 and great strength and hardness to protect the display panel DP from external impact.

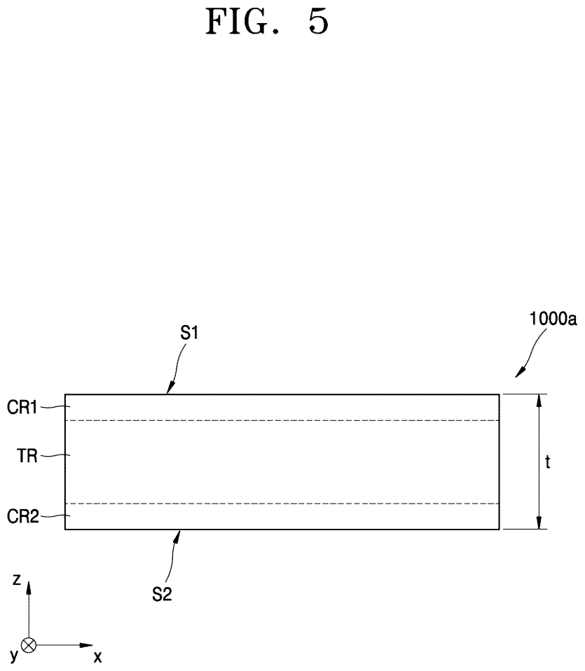

FIG. 5 is a schematic cross-sectional view of the glass article 1000a of the flat-plate shape that is described above with reference to FIG. 1A.

Referring to FIG. 5, the glass article 1000a may include a first surface S1, a second surface S2, and side surfaces. In the glass article 1000a with the flat-plate shape, the first surface S1 and the second surface S2 may be the main surfaces having large areas, and the side surfaces may be outer surfaces connecting the first surface S1 to the second surface S2.

The first surface S1 and the second surface S2 may face each other in a thickness direction (e.g., a z direction). In case that the glass article 1000a transmits light like the cover window CW of the electronic device 1 described above with reference to FIGS. 2 and 4, the light may be mainly introduced through one of the first surface S1 and the second surface S2 and pass through another one of the first surface S1 and the second surface S2.

The thickness t of the glass article 1000a may be defined as a distance between the first surface S1 and the second surface S2. The thickness t of the glass article 1000a is not limited thereto, but may be less than or equal to about 100 μm. For example, the thickness t of the glass article 1000a may be in a range of about 20 μm to about 100 μm. In an embodiment, the thickness t of the glass article 1000a may be less than or equal to about 80 μm. In another embodiment, the thickness t of the glass article 1000a may be less than or equal to about 75 μm. In another embodiment, the thickness t of the glass article 1000a may be less than or equal to about 70 μm. In another embodiment, the thickness t of the glass article 1000a may be less than or equal to about 60 μm. In another embodiment, the thickness t of the glass article 1000a may be less than or equal to about 65 μm. In another embodiment, the thickness t of the glass article 1000a may be less than or equal to about 50 μm. In another embodiment, the thickness t of the glass article 1000a may be less than or equal to about 30 μm. In an embodiment, the thickness t of the glass article 1000a may be in a range of about 20 μm to about 50 μm. For example, the thickness t of the glass article 1000a may be about 30 μm. The glass article 1000a may have a uniform thickness t, but the disclosure is not limited thereto. The glass article 1000a may have different thicknesses t in different portions.

The glass article 1000a may be reinforced and have a specific stress profile inside the glass article 1000a. The reinforced glass article 1000a may prevent the generation of cracks by external impact, the propagation of the cracks, breakage, and the like better than the glass article 1000a before reinforcement. The glass article 1000a reinforced through the reinforcement process may have various stresses for each portion. For example, compression regions CR1 and CR2, where compressive stress is applied, may be located near the surface of the glass article 1000a, for example, near the first surface S1 and the second surface S2, and a tensile region TR, where tensile stress is applied, may be located inside the glass article 1000a. The boundaries between the compression regions CR1 and CR2 and the tensile region TR may have stress values of 0. The compressive stress in one of the compression regions CR1 and CR2 may have a stress value varying according to the location (for example, the depth from the surface). The tensile region TR may also have a stress value varying according to the depth from the first surface S1 and the second surface S2.

In the glass article 1000a, the locations of the compression regions CR1 and CR2, the stress profiles in the compression regions CR1 and CR2, the compression energy in the compression regions CR1 and CR2, or the tensile energy in the tensile region TR may greatly affect the mechanical properties of the glass article 1000a, for example, surface strength.

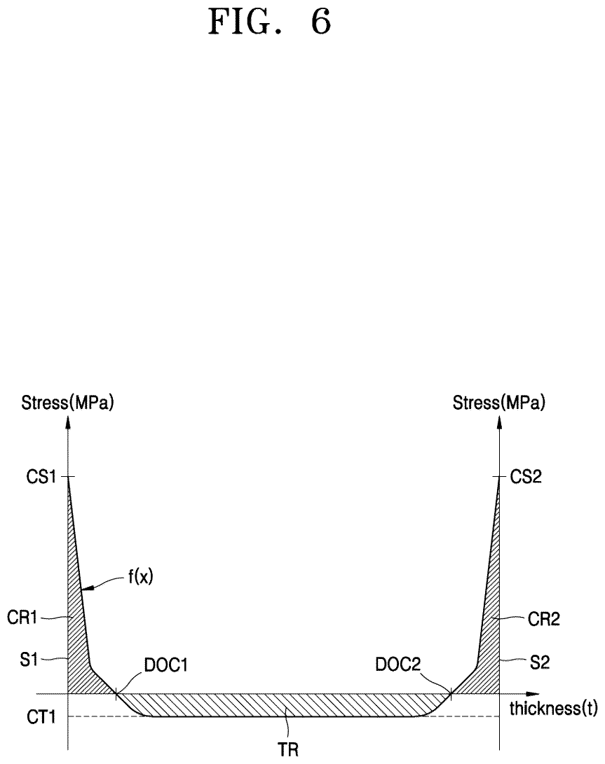

FIG. 6 is a graph showing stress profiles of the glass article 1000a (See FIG. 5), according to an embodiment. In the graph of FIG. 6, the x axis indicates the thickness direction of the glass article 1000a (See FIG. 5). In FIG. 6, the compressive stress has a positive value, while the tensile stress has a negative value. In the specification, the magnitudes of the compressive stress/tensile stress refer to the size of the absolute value without regard to its sign.

Referring to FIG. 5 and FIG. 6, the glass article 1000a may include a first compression region CR1 extending (or expanding) from the first surface S1 to a first compression depth DOC1 and a second compression region CR2 extending (or expanding) from the second surface S2 to a second compression depth DOC2. The tensile region TR may be located between the first compression depth DOC1 and the second compression depth DOC2. The general stress profile in the glass article 1000a may have a mutual symmetrical structure between regions on the first surface S1 and regions on the second surface S2 with respect to the center in the direction of thickness t. Although not shown in FIG. 6, compression regions and tensile regions may be located between opposite side surfaces of the glass article 1000a in a similar manner.

The first compression region CR1 and the second compression region CR2 may resist external impact and thus prevent the generation of cracks in the glass article 1000a and the breakage of the glass article 1000a. The greater the maximum compressive stresses CS1 and CS2 of the first compression region CR1 and the second compression region CR2 become, the more the strength of the glass article 1000a increases. Because external impact is generally delivered through the surface of the glass article 1000a, it is advisable to have the maximum compressive stresses CS1 and CS2 on the surface of the glass article 1000a in terms of durability. The compressive stresses of the first compression region CR1 and the second compression region CR2 may be the greatest on the surface and tend to generally decrease towards the inside of the first compression region CR1 and the second compression region CR2.

The first compression depth DOC1 and the second compression depth DOC2 may prevent cracks or grooves, which are formed in the first surface S1 and the second surface S2, from propagating to the tensile region TR inside the glass article 1000a. The greater the first compression depth DOC1 and the second compression depth DOC2 become, the better the propagation of the cracks, etc. may be prevented. The points corresponding to the first compression depth DOC1 and the second compression depth DOC2 may correspond to the boundary between the compression regions CR1 and CR2 and the tensile region TR, and the stress values of the points become 0.

Throughout the glass article 1000a, the tensile stress in the tensile region TR may be balanced with the compressive stresses in the compression regions CR1 and CR2. In other words, the total compressive stress in the glass article 1000a (for example, the compression energy) may be identical to the total tensile stress (for example, the tensile energy). The stress energy accumulated in a portion of the glass article 1000a with a uniform width in the thickness direction may be calculated as the integral value of the stress profile. In case that the stress profile in the glass article 1000a with the thickness t is represented as the function f(x), the following Equation 1 may be established.

$${\int }_{0}^{t} f ( x ) dx = 0 \qquad [ Equation 1 ]$$

The greater the magnitude of the tensile stress in the glass article 1000a is, the more violently the broken pieces scatter in case that the glass article 1000a is broken, resulting in a possible fracture from the inside of the glass article 1000a. The maximum tensile stress meeting the vulnerability standard of the glass article 1000a is not limited thereto and may satisfy the following Equation 2.

$${CT}_{1} \leq - 38.7 \times ln ( t ) + 48.2 \qquad [ Equation 2 ]$$

In some embodiments, the maximum tensile stress CT1 may be in a range of about 85 MPa to about 100 MPa. It may be advisable for the maximum tensile stress CT1 to be at least about 75 MPa to improve mechanical properties such as strength. In an embodiment, the maximum tensile stress CT1 may be in a range of about 75 MPa to about 85 MPa, but the disclosure is not limited thereto.

The maximum tensile stress CT1 of the glass article 1000a may be generally at the center of the glass article 1000a in the thickness direction. For example, the maximum tensile stress CT1 of the glass article 1000a may be at a depth in a range of about 0.4 t to about 0.6 t. For example, the maximum tensile stress CT1 of the glass article 1000a may be at a depth in a range of about 0.45 t to about 0.55 t. For example, the maximum tensile stress CT1 of the glass article 1000a may be at a depth of about 0.5 t.

To increase the strength of the glass article 1000a, it is advisable that the compressive stress and the compression depths DOC1 and DOC2 are great; however, the increase in the compression energy leads to the increase in the tensile energy, which in turn increases the maximum tensile stress CT1. It is advisable to adjust the stress profiles to keep the compression energy low while maintaining high maximum compressive stresses CS1 and CS2 and great compression depths DOC1 and DOC2 to both achieve great strength and meet the vulnerability standard. To this end, the glass article 1000a may be prepared from a glass composition containing specific components in designated amounts. According to the composition ratio of the components included in the glass composition, the prepared glass article 1000a may have not only great strength but also flexibility and physical properties to be applied to a foldable electronic device.

According to an embodiment, the glass composition forming the glass article 1000a may include SiO₂ in a range of about 60 mol % to about 70 mol %, Al₂O₃ in a range of about 5 mol % to about 15 mol %, Na₂O in a range of about 5 mol % to about 15 mol %, Li₂O in a range of about 5 mol % up to about 15 mol %, and MgO in a range of about 0 mol % to about 5 mol % with respect to the total weight of the glass composition. According to an embodiment, the glass composition forming the glass article 1000a may not include ZrO₂. According to an embodiment, the glass composition forming the glass article 1000a may not include K₂O.

Each component of the glass composition is described in more detail below.

SiO₂ may form the framework of glass, increase chemical durability, and decrease the generation of cracks in case that a crack (an indentation) is generated on the glass surface. SiO₂ may be a network former oxide forming the glass network, and the glass article 1000a prepared using SiO₂ may have reduced thermal expansion coefficients and improved mechanical strength. To achieve such an increase and decrease, the content of SiO₂ may be greater than or equal to about 60 mol %. For sufficient fusibility, the content of SiO₂ in the glass composition may be less than or equal to about 70 mol %.

Al₂O₃ may increase the crushability of glass. For example, Al₂O₃ may reduce the number of glass fragments in case that glass is broken. Al₂O₃ may be an intermediate oxide bonded to SiO₂ that forms the network structure. Al₂O₃ may improve the ion exchange performance during chemical strengthening and may act as an active ingredient that increases surface compressive stress after the strengthening. In case that the content of Al₂O₃ is at least about 5 mol %, the above functions may be effectively performed. To maintain the acid resistance and fusibility of glass, it is advisable that the content Al₂O₃ is less than or equal to about 15 mol %.

Na₂O may form surface compressive stress through ion exchange and improve the fusibility of glass. Na₂O may form ionic bonds with oxygen in SiO₂ forming the network structure, thus generating nonbridging oxygen in the SiO₂ network structure. The increase in nonbridging oxygen may improve the flexibility of the network structure, and the glass article 1000a may have the physical properties to be applied to the foldable electronic device. It is advisable that the content of Na₂O is at least about 5 mol % to effectively perform the above functions. In terms of the acid resistance of the glass article 1000a, it is advisable that the content of Na₂O is less than or equal to about 15 mol %.

Similar to Na₂O described above, Li₂O may form surface compressive stress through ion exchange and improve the fusibility of glass. Li₂O may form ionic bonds with oxygen in SiO₂ forming the network structure, thus forming nonbridging oxygen in the SiO₂ network structure. The increase in nonbridging oxygen may improve the flexibility and shock absorption of the network structure, and the glass article 1000a may have the physical properties applicable to a foldable electronic device. It is desirable that the content of Li₂O is at least about 5 mol % to effectively perform the above functions. However, in terms of the thermal resistance of the glass article 1000a, it is desirable that the content of Li₂O is less than or equal to about 15 mol %.

MgO may improve the surface strength of glass and reduce the temperature at which glass is formed. MgO may be a network modifier oxide that reforms the network structure of SiO₂ that forms the network structure. MgO may reduce the refractive index of glass and adjust the coefficients of thermal expansion and the elastic modulus of glass. In case that the content of MgO is more than 0 mol %, the above functions may be significantly performed. However, in terms of the fusibility of the glass article 1000a, it may be advisable that the content of MgO in the glass article 1000a is less than or equal to about 5 mol %.

According to an embodiment, the glass composition may satisfy Relation 1 and/or Relation 2 below.

0.3≤Al₂O₃/(the sum of Na₂O and Li₂O)≤1.0 [Relation 1]

In Relation 1, Al₂O₃, Na₂O, and Li₂O may be a content (mol %) of respective components.

According to an embodiment, the glass composition may satisfy Relation 2 below.

0.3≤Al₂O₃/(the sum of Na₂O, Li₂O, and MgO)≤1.0 [Relation 2]

In Relation 2, Al₂O₃, Na₂O, Li₂O, and MgO may be a content (mol %) of respective components.

The network structure, which is formed as the glass composition including SiO₂ and Al₂O₃, may have flexibility after the addition of Na₂O and Li₂O. Because of the addition of Na₂O and Li₂O, Na ions or Li ions may form ionic bonds with oxygen atom between bonds forming the network structure, for example, bonds between SiO₂, such that the amount of nonbridging oxygen may increase. The increase in nonbridging oxygen in the network structure may indicate that the bonds of the network structure are broken or open, allowing the network structure of glass to obtain flexibility. The glass composition may include Na₂O in a content of at least about 5 mol % and Li₂O in a content of at least about 5 mol % to make the manufactured glass article 1000a have sufficient flexibility.

As the glass composition includes a relatively excessive amount of Na₂O and Li₂O, the glass composition may have weak mechanical strength. To supplement the vulnerability, the glass composition may include Al₂O₃, and according to Relation 1 above, the ratio of Al₂O₃ to the sum of Na₂O and Li₂O may be adjusted to be in a range of 0.3 to 1.0 such that the mechanical strength of the network structure may increase. According to an embodiment, the glass composition may have the ratio of Al₂O₃ to the sum of Na₂O and Li₂O (or a R ratio) in a range of 0.3 to 1.0.

As the ratio of Al₂O₃ to the sum of Na₂O and Li₂O (the R ratio) included in the glass composition increases, Al₂O₃ may have a tetrahedron crystal structure including SiO₂. In the network structure including SiO₂, SiO₂ may have a tetrahedron crystal structure (SiO₄), and in case that the contents of Na₂O and Li₂O increase compared to the content of Al₂O₃, Al₂O₃ may also have a tetrahedron crystal structure (AlO₄). The content of nonbridging oxygen formed due to the addition of Na₂O and Li₂O may be reduced, and the ion mobility of the glass composition may increase. The increase in ion mobility may indicate that the number of ions moving during chemical strengthening in the process of forming the glass article 1000a and the ion penetration depth increase, and the mechanical strength of the surface of the glass article 1000a may be improved. However, because flexibility decreases by as much as the mechanical strength of the glass composition increases, the ratio of Al₂O₃ to the sum of Na₂O and Li₂O (the R ratio) may be formed to be in a range of about 0.3 to about 1.0 to achieve both sufficient mechanical strength and flexibility in the embodiment.

In case that the ratio of Al₂O₃ to the sum of Na₂O and Li₂O (the R ratio) included in the glass composition is at least 0.3, the contents of Na₂O and Li₂O may increase, and Na₂O and Li₂O with increased contents may break the network structure of SiO₂, thereby increasing the interatomic distance in the network structure. Accordingly, a substantial amount of extra space may be formed in the network structure of SiO₂, and thus, shock absorption and flexibility may be improved.

In an embodiment, as the ratio of Al₂O₃ to the sum of Na₂O and Li₂O (the R ratio) included in the glass composition has a value in a range of about 0.3 to about 1.0, the flexibility of the glass article 1000a, strength against external impact, and shock absorption may be improved.

The glass composition according to an embodiment may include Na₂O and Li₂O as materials forming nonbridging oxygen in the network structure of SiO₂ as ionic bonds with oxygen atoms in SiO₂ are formed, but may not include K₂O. The reinforcement process, during which the ion exchange is formed in the process of forming the glass article 1000a, may be performed only once. During the chemical strengthening, the glass composition may not include K₂O to facilitate the migration of a great number of Na ions or Li ions to the surface of the glass article 1000a. The glass composition according to an embodiment may satisfy both relatively high Young's modulus and relatively low brittleness as the glass composition does not include K₂O.

In an embodiment, the glass composition may include SiO₂ of about 65.3 mol %, Al₂O₃ of about 8.9 mol %, Na₂O of about 12.7 mol %, Li₂O of about 10.01 mol %, and MgO of about 3.0 mol %, and the R ratio of the glass composition according to Relation 1 may be about 0.39.

In addition to the components stated above, the glass composition may further include a component such as SnO₂, Y₂O₃, La₂O₃, Nb₂O₅, Ta₂O₅, and Gd₂O₃ according to an embodiment. In an embodiment, the glass composition may further include a small amount of Sb₂O₃, CeO₂, and/or As₂O₃ as a clarifier.

The glass composition having the above composition may be molded into plate glass in various manners. When the glass composition is molded into the plate glass, the glass composition may undergo additional processes to be manufactured into the glass article 1000a that is applicable to the electronic device 1. However, the disclosure is not limited thereto. The glass composition may not be formed into plate glass and may be directly molded into the glass article 1000a applicable to a product without additional molding processes.

As described above, the glass article 1000a prepared from the glass composition according to an embodiment may have characteristics and physical properties that are applied to a foldable electronic device. For example, the glass article 1000a may have the flexibility to be folded and unfolded and have chemical properties and strength to be applicable to the cover window CW of the electronic device 1. In case that the glass article 1000a prepared from the glass composition according to an embodiment is folded, the generation of creases in the folding area may be prevented or reduced.

The impact resistance of the glass article 1000a may be related to various mechanical and chemical properties of the glass article 1000a. For example, the glass article 1000a may have physical properties such as the coefficient of thermal expansion, transition temperature, density, Young's modulus, Poisson's ratio, Vickers hardness, fracture toughness, and brittleness. According to an embodiment, the glass article 1000a prepared from the glass composition described above may satisfy the following Properties.

### [Properties]

i) coefficient of thermal expansion (10⁻⁷ K⁻¹): 85*10⁻⁷ K⁻¹ to 120*10⁻⁷ K⁻¹
ii) glass transition temperature (T_{g}): 425° C. to 525° C.
iii) density: 2.38 g/cm³ to 2.48 g/cm³
iv) elastic modulus: 75 GPa to 85 GPa
v) Poisson's ratio: 0.20 to 0.28
vi) Vickers hardness: 5.50 GPa to 6.50 GPa
vii) fracture toughness: 0.75 MPa*m^{0.5} to 0.85 MPa*m^{0.5}
viii) brittleness: 4.9 μm^{-0.5} to 5.6 μm^{-0.5}

In an embodiment, the elastic modulus of the glass article 1000a may be in a range of about 80 GPa to about 85 GPa. In an embodiment, the elastic modulus of the glass article 1000a may be in a range of about 82 GPa to about 85 GPa.

In an embodiment, the brittleness of the glass article 1000a may be in a range of about 4.9 μm^{-0.5} to about 5.4 μm^{-0.5}. In an embodiment, the brittleness of the glass article 1000a may be in a range of about 4.9 μm^{-0.5} to about 5.2 μm^{-0.5}.

Hereinafter, embodiments are described in more detail based on the Preparation Examples below.

### Preparation Example 1: Preparation of Glass Article

According to Table 1 below, multiple glass substances with various compositions were prepared and classified into SAMPLE #1, SAMPLE #2, SAMPLE #3, SAMPLE #4, SAMPLE #5, SAMPLE #6, SAMPLE #7, SAMPLE #8, and SAMPLE #9, and glass articles were manufactured for each sample. The glass article of each sample was manufactured with a thickness of about 50 μm. Table 1 shows the composition of each sample.

The coefficient of thermal expansion (CTE), the glass transition temperature (Tg), the density (φ, the elastic modulus (E), the Poisson's ratio (v), the Vickers hardness (Hv), the fracture toughness (K_{IC}), the brittleness (B), and the figure of merit (FOM) for free volume of the glass article of each sample were measured and organized in Table 2 below.

Here, the glass transition temperature (Tg) was determined using Differential Thermal Analysis (DTA) equipment. 5 g of each glass sample was prepared and heated at a rate of 10 K/min to the glass transition temperature range. The coefficient of thermal expansion was determined using Thermo mechanical analyzer (TMA) equipment. A specimen with a size of 10×10×13 mm³ was prepared for each composition and heated at a rate of 10 K/min to the glass transition temperature range.

The Poisson's ratio (v) was determined using an elastic modulus tester. A specimen with a size of 10×20×3 mm³ was prepared for each composition, and the stress and strain of the specimen were measured.

The Vickers hardness (Hv) and the fracture toughness (K_{IC}) were calculated using Equation 3 and Equation 4 below by applying a load of 4.9 N for 30 seconds with a Vickers hardness tester using a 19 μm diamond tip.

$${H}_{V} = 1.854 \cdot \frac{F}{{α}^{2}} \qquad [ Equation 3 ]$$

In Equation 3, H_{V} may be a Vickers hardness, F may be a load, and a may be an indentation length.

$$\frac{{K}_{IC} \cdot ϕ}{{H}_{V} \cdot {a}^{\frac{1}{2}}} = 0.15 \cdot K \cdot {( \frac{c}{a} )}^{- \frac{3}{2}} \qquad [ Equation 4 ]$$

In Equation 4, K_{IC} may be a fracture toughness, ϕ may be a constraint index about 3, H_{V} may be a Vickers hardness, K may be a constant of 3.2, c may be a crack length, and a may be an indentation length.

The brittleness (B) was calculated using Equation 5 below by applying a load of 4.9 N for 30 seconds with a Vickers hardness tester.

$$B = γ {P}^{- 1 / 4} \frac{{C}^{3 / 2}}{a} \qquad [ Equation 5 ]$$

In Equation 5, B may be a brittleness, γ may be a constant of 2.39N^{1/4}/μm^{1/2}, P may be an indentation load, a may be an indentation depth, and C may be a crack length.

The crack generation load was measured using a Vickers hardness tester.

The FOM for free volume was calculated using Equation 6, Equation 7, Equation 8, and Equation 9 below.

$$The FOM for free volume = {G}_{1 C} * {( 1 / B )}^{{6}^{⋆}} {E}_{abs} * ( 1 / {T}_{g} ) \qquad [ Equation 6 ]$$

In Equation 6, B may be a brittleness and T_{g} may be a glass transition temperature.

$${G}_{1 C} = ( {K}_{IC}^{2} ( 1 - {v}^{2} ) ) / E \qquad [ Equation 7 ]$$

In Equation 7, K_{IC} may be a fracture toughness, v may be a Poisson's ratio, and E may be an elastic modulus.

$${E}_{abs} = {σ}^{2 ⋆} ( 1 - v ) / E \qquad [ Equation 8 ]$$

In Equation 8, v may be a Poisson's ratio and E may be an elastic modulus.

$$σ = ( E * α * {ρ}^{2} ) / ( 1 - v ) \qquad [ Equation 9 ]$$

In Equation 9, v may be a Poisson's ratio, E may be an elastic modulus, a may be a coefficient of thermal expansion, and p may be a density.

TABLE 1

| | | | | | Li₂O | Li₂O | | R | R′ |
|---|---|---|---|---|---|---|---|---|---|
| | SiO₂ | Al₂O₃ | Na₂O | K₂O | (LiAlSi₂O₆) | (Li₂CO₃) | MgO | ratio | ratio |
| Sample#1 | 65.16 | 8.86 | 9.72 | 3.2 | 10.08 | — | 2.99 | 0.39 | 0.34 |
| Sample#2 | 65.16 | 11.62 | 8.69 | 2.86 | 9.01 | — | 2.67 | 0.57 | 0.5 |
| Sample#3 | 65.16 | 14.94 | 7.45 | 2.45 | 7.72 | — | 2.29 | 0.85 | 0.75 |
| Sample#4 | 61.16 | 9.88 | 10.84 | 3.57 | 9.67 | 1.57 | 3.33 | 0.39 | 0.34 |
| Sample#5 | 67.16 | 8.35 | 9.16 | 3.02 | 8.17 | 1.33 | 2.82 | 0.39 | 0.34 |
| Sample#6 | 65.16 | 8.86 | 1.22 | 3.2 | 7.58 | — | 2.99 | 0.39 | 0.34 |
| Sample#7 | 65.16 | 8.86 | 14.72 | 3.2 | 5.08 | — | 2.99 | 0.39 | 0.34 |
| Sample#8 | 65.16 | 8.86 | 9.72 | 8.2 | 5.08 | — | 2.99 | 0.39 | 0.34 |
| Sample#9 | 65.16 | 8.86 | 9.72 | — | 8.67 | 4.61 | 2.99 | 0.39 | 0.34 |

TABLE 2

| | Coefficient | | | | | | | | |
|---|---|---|---|---|---|---|---|---|---|
| | of | Glass | | | | | | | |
| | thermal | transition | | Elastic | | Vicker's | Fracture | | Free |
| | expansion | temperature | Density | modulus | Poisson's | hardness | toughness | Brittleness | volume |
| | (10⁻⁷K⁻¹) | (° C.) | (g/cm³) | (GPa) | ratio | (Hv) | (MPa*m^{0.5}) | (μm^{-0.5}) | (KJ/m²)²/K |
| Sample | 90.1 | 497 | 2.475 | 80 | 0.258 | 623 | 1.07 | 5.69 | 36.59 |
| #1 | | | | | | | | | |
| Sample | 89.2 | 513 | 2.434 | 82 | 0.229 | 638 | 1.08 | 5.78 | 28.80 |
| #2 | | | | | | | | | |
| Sample | 76.0 | 585 | 2.452 | 82 | 0.229 | 631 | 1.02 | 6.07 | 10.82 |
| #3 | | | | | | | | | |
| Sample | 108 | 468 | 2.473 | 82 | 0.229 | 626 | 1.03 | 5.98 | 66.25 |
| #4 | | | | | | | | | |
| Sample | 97.4 | 478 | 2.449 | 78 | 0.229 | 613 | 1.05 | 5.71 | 46.56 |
| #5 | | | | | | | | | |
| Sample | 108 | 477 | 2.437 | 79 | 0.229 | 613 | 1.04 | 5.84 | 59.54 |
| #6 | | | | | | | | | |
| Sample | 110 | 485 | 2.445 | 77 | 0.229 | 597 | 0.99 | 5.93 | 54.69 |
| #7 | | | | | | | | | |
| Sample | 112 | 481 | 2.440 | 74 | 0.258 | 606 | 0.97 | 6.16 | 54.11 |
| #8 | | | | | | | | | |
| Sample | 96.2 | 481 | 2.434 | 84 | 0.229 | 619 | 1.22 | 4.98 | 65.05 |
| #9 | | | | | | | | | |

Referring to Table 1 and Table 2, Sample #1 to Sample #8 are glass articles prepared from glass compositions including Na₂O, Li₂O, and K₂O and having the ratio of Al₂O₃ to the sum of Na₂O, Li₂O, and K₂O (or the R ratio) of at least 3 and the ratio of Al₂O₃ to the sum of Na₂O, Li₂O, K₂O, and MgO (or a R′ ratio) of at least 3. Sample #9 are glass articles prepared from the glass composition that does not contain K₂O and has the ratio of Al₂O₃ to the sum of Na₂O and Li₂O (or the R ratio) of at least 3 and the ratio of Al₂O₃ to the sum of Na₂O, Li₂O, and MgO (or the R′ ratio) of at least 3.

The elastic modulus of Sample #9 is 84 GPa, which is relatively higher than the elastic moduli of Sample #1 to Sample #8. The brittleness of Sample #9 is 4.98 μm^{-0.5}, which is relatively lower than the brittleness of Sample #1 to Sample #8. In case that the glass article has a relatively high elastic modulus, the glass article may be deformed less under a same pressure, and thus, the deformation degree may decrease in case that the glass article is folded in the folding area. In general, an increase in the elastic modulus tends to lead to higher brittleness, but in the case of Sample #9 which does not include K₂O, the elastic modulus is relatively high, while the brittleness is low compared to Sample #1 to Sample #8 which include K₂O. For example, in the case of the glass article prepared from the glass composition according to embodiments, where the elastic modulus falls within the range of about 75 GPa to about 85 GPa and the brittleness is low within the range of about 4.9 μm^{-0.5} to about 5.6 μm^{-0.5}, deformation and/or crease formation in case that the glass article is folded in the folding area may be reduced or prevented, while also improving impact resistance.

The FOM value for the free volume of Sample #9 is relatively greater than the FOM values for the free volume of Sample #1 to Sample #8. Free volume may be a space where polymer chains may freely move, and as described with reference to Equation 6 to Equation 9, the FOM values of the free volume are determined based on brittleness, glass transition temperature, fracture toughness, Poisson's ratio, elastic modulus, coefficients of thermal expansion, and density. As the FOM value of the free volume increases, the impact resistance of the glass article may be improved. In case that numerical ranges of the above-described physical properties, including brittleness, glass transition temperature, fracture toughness, Poisson's ratio, elastic modulus, coefficients of thermal expansion, and density, are satisfied, and K₂O is not included as in Sample #9, impact resistance may be further improved (or increased) compared to cases where numerical ranges of the above physical properties are not be satisfied, or cases that include K₂O.

According to embodiments, a glass composition in which impact resistance is improved while creases are reduced in a glass folding area, a glass article prepared from the glass composition, and a electronic device may be implemented. However, the scope of the disclosure is not limited by the effects.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A glass article comprising:
a glass composition comprising SiO₂ in a range of about 60 mol % to about 70 mol %, Al₂O₃ in a range of about 5 mol % to about 15 mol %, Na₂O in a range of about 5 mol % to about 15 mol %, Li₂O in a range of about 5 mol % to about 15 mol %, and MgO greater than 0 mol % and less than or equal to about 5 mol % with respect to a total weight of the glass composition, wherein
the glass composition satisfies Relation 1, and
a thickness of the glass article is in a range of about 20 μm to about 100 μm.
0.3≤Al₂O₃/(a sum of Na₂O and Li₂O)≤1.0 [Relation 1]
in Relation 1, Al₂O₃, Na₂O and Li₂O represent contents of respective components in mol %.

2. The glass article of claim 1, wherein an elastic modulus of the glass article is in a range of about 75 GPa to about 85 GPa.

3. The glass article of claim 1, wherein a brittleness of the glass article is in a range of about 4.9 μm^{-0.5} to about 5.6 μm^{-0.5}.

4. The glass article of claim 1, wherein a coefficient of thermal expansion of the glass article is in a range of about 85*10⁻⁷ K⁻¹ to about 120*10⁻⁷ K⁻¹.

5. The glass article of claim 1, wherein a glass transition temperature of the glass article is in a range of about 425° C. to about 525° C.

6. The glass article of claim 1, wherein a density of the glass article is in a range of about 2.38 g/cm³ to about 2.48 g/cm³.

7. The glass article of claim 1, wherein a Poisson's ratio of the glass article is in a range of about 0.20 to about 0.28.

8. The glass article of claim 1, wherein a Vickers hardness of the glass article is in a range of about 5.50 GPa to about 6.50 GPa.

9. The glass article of claim 1, wherein a fracture toughness of the glass article is in a range of about 0.75 MPa*m^{0.5} to about 0.85 MPa*m^{0.5}.

10. The glass article of claim 1, wherein the glass article is foldable.

11. The glass article of claim 1, wherein the glass composition further satisfies Relation 2,
0.3≤Al₂O₃/(a sum of Na₂O, Li₂O, and MgO)≤1.0 [Relation 2]
in Relation 2, Al₂O₃, Na₂O, Li₂O and MgO represent contents of respective components in mol %.

12. A glass composition comprising:
SiO₂ in a range of about 60 mol % to about 70 mol %, Al₂O₃ in a range of about 5 mol % to about 15 mol %, Na₂O in a range of about 5 mol % to about 15 mol %, Li₂O in a range of about 5 mol % to about 15 mol %, and MgO greater than 0 mol % and less than or equal to about 5 mol % with respect to a total weight of the glass composition, wherein
the glass composition satisfies Relation 1,
0.3≤Al₂O₃/(a sum of Na₂O and Li₂O)≤1.0 [Relation 1]
in Relation 1, Al₂O₃, Na₂O and Li₂O represent contents of respective components in mol %.

13. A display device comprising:
a display panel comprising a plurality of pixels; and
a cover window disposed on the display panel, wherein
the cover window comprises, as a glass composition, SiO₂ in a range of about 60 mol % to about 70 mol %, Al₂O₃ in a range of about 5 mol % to about 15 mol %, Na₂O in a range of about 5 mol % to about 15 mol %, Li₂O in a range of about 5 mol % to about 15 mol %, and MgO greater than 0 mol % and less than or equal to about 5 mol % with respect to a total weight of the cover window,
the glass composition satisfies Relation 1,
a thickness of the cover window is in a range of about 20 μm to about 100 μm.
0.3≤Al₂O₃/(a sum of Na₂O and Li₂O)≤1.0 [Relation 1]
in Relation 1, Al₂O₃, Na₂O and Li₂O represent contents of respective components in mol %.

14. The display device of claim 13, wherein an elastic modulus of the cover window is in a range of about 75 GPa to about 85 GPa.

15. The display device of claim 13, wherein a brittleness of the cover window is in a range of 4.9 μm^{-0.5} to about 5.6 μm^{-0.5}.

16. The display device of claim 13, wherein a coefficient of thermal expansion of the cover window is in a range of about 85*10⁻⁷ K⁻¹ to about 120*10⁻⁷ K⁻¹.

17. The display device of claim 13, wherein a glass transition temperature of the cover window is in a range of about 425° C. to about 525° C.

18. The display device of claim 13, wherein a density of the cover window is in a range of about 2.38 g/cm³ to about 2.48 g/cm³.

19. The display device of claim 13, wherein a Poisson's ratio of the cover window is in a range of about 0.20 to about 0.28.

20. The display device of claim 13, wherein a Vickers hardness of the cover window is in a range of about 5.50 GPa to about 6.50 GPa.

21. The display device of claim 13, wherein a fracture toughness of the cover window is in a range of about 0.75 MPa*m^{0.5} to about 0.85 MPa*m^{0.5}.

22. An electronic device comprising:
a display panel comprising a plurality of pixels;
a cover window disposed on the display panel, wherein
the cover window comprises, as a glass composition, SiO₂ in a range of about 60 mol % to about 70 mol %, Al₂O₃ in a range of about 5 mol % to about 15 mol %, Na₂O in a range of about 5 mol % to about 15 mol %, Li₂O in a range of about 5 mol % to about 15 mol %, and MgO greater than 0 mol % and less than or equal to about 5 mol % with respect to a total weight of the cover window,
the glass composition satisfies Relation 1,
a thickness of the cover window is in a range of about 20 μm to about 100 μm.
0.3≤Al₂O₃/(a sum of Na₂O and Li₂O)≤1.0 [Relation 1]
in Relation 1, Al₂O₃, Na₂O and Li₂O represent contents of respective components in mol %.

23. The electronic device of claim 22 includes a mobile phone, a smartphone, a tablet PC, a mobile communication terminal, a personal digital assistant, an e-book terminal, a portable multimedia player (PMP), a navigation device, an ultra-mobile PC (UMPC), a TV, a laptop, a monitor, a billboard, or an Internet of Things (IoT) device.
